(19) United States
(12) Patent Application Publication
(10) Pub. No.: US 2017/0231374 A1
(43) Pub. Date: Aug. 17, 2017

(54) HANGER FOR AN ELECTRONIC DEVICE

(71) Applicant: IMACK LAYDERA-COLLINS, Benton, LA (US)

(72) Inventor: IMACK LAYDERA-COLLINS, Benton, LA (US)

(73) Assignee: ADVENTECH INC., Benton, LA (US)

(21) Appl. No.: 15/011,987

(22) Filed: Feb. 1, 2016

Related U.S. Application Data
(60) Provisional application No. 62/125,807, filed on Feb. 2, 2015.

(51) Int. Cl. A45F 5/00; H05K 7/14

(52) U.S. Cl. CPC A45F 5/004; H05K 7/1415; A45F 2005/006

(57) ABSTRACT

This invention is for a portable electronic device hanger, which is specifically designed to be wore as a necklace. The hanger is designed as compact as possible, lightweight and with easy accessibility to the electronic device, including an adjustable lanyard which is fully retractable to facilitate storage. The electronic device is easily attached or detached from the hanger.

### CROSS-REFERENCE TO RELATED APPLICATION

This application claims the benefit of the U.S. Provisional Application No. 62/125,807 filed Feb. 2, 2015, which hereby is incorporated by reference, and it is a substitute specification for the application Ser. No. 15/011,987 filed on Feb. 1, 2016.

### BACKGROUND OF THE INVENTION

1. Field of the Invention
The present invention relates to portable electronic equipment such as I-pods and cell phones. More particularly to a holder for such portable electronic devices, designed to use around the neck of a user for easy accessibility and operation of the device, while allowing easy attachment or detachment of the electronic device.

2. Description of the Related Art
Modern electronic equipment such as cell phones has been designed very compact for easy portability. Typical storage places such as purses, pockets, and belt holders does not allow a good monitoring of incoming calls or notifications. The attempted solutions have not sufficiently addressed the needs of the users who have no other choice than consistently carrying the device on their hands. Many of the prior inventions are hand straps, belt holders, arm holders, head straps which have not succeeded in providing the accessibility, comfort and flexibility demanded by the consumers. Other inventions rely on wireless communications such as blue tooth devices to keep the device in stored position while in use. But even these devices do not offer the desired full interface with the device features. The attempted solutions in general have not provided an easy access to the device or means of monitoring, operating or interfacing with the device in a convenient manner. Therefore, it is a demand for an alternative method of carrying the device that allows that close interface with the user while still maintaining the portability.

### SUMMARY OF THE INVENTION

The electronic device carrier of the present invention arises as a need to free the user's hands from carrying the device while keeping it easily accessible for retrieval and constant monitoring and operation. The invention is intended to be wearable as a necklace. As such it needs to be as compact as possible, lightweight, easy to remove, provide full accessibility to the electronic device, comfortable to wear, and located in a part of the user's body that allows constant monitoring and operation of the electronic device without removal. The electronic device hanger object of the present invention offers self-contained and retractable strap for wearing the hanger and attached electronic device around the user's neck. The hanger allows adjusting the strap length along the user's chest, for accessibility, comfort or proper use. Also, the strap can be fully retrieved inside the carrier for storage avoiding the problem of tangling of the strap with other objects inside the purse or pocket. An added feature for the device object of the present invention is the possibility of using a cellphone as a body video camera, since it is possible to activate the video feature while the unit hangs in the user's neck as a regular necklace. Under this mode, the user could adjust the camera along his chest for the perfect viewing position.

Many other advantages are obvious for such hands-free carrier such as preventing the device from falling to the ground or water, preventing from leaving the electronic device in odd places, allowing easy device detachment if required, while still having full accessibility to the electronic device.

The hanger could be specifically configured for every electronic device by providing the necessary gripping means. These gripping means could take many shapes which are intrinsic to how the device should be best attached or removed from the holder object of the present invention.

The above summary is not intended to describe each illustrated embodiment of every possible implementation. These and other features, aspects, and advantages of the present invention will become better understood with regard to the following description, appended claims, and accompanying drawings.

### BRIEF DESCRIPTION OF THE DRAWINGS

The accompanying figures, where like reference numerals refer to identical or functional similar elements throughout the separate views, which are not true to scale, and which, together with the detailed descriptions below, are incorporated in and form part of the application, serve to illustrate further various embodiments and to explain various principles and advantages in accordance to the present invention. Advantages of embodiments of the present invention will be apparent from the following detail description of exemplary embodiments thereof, which should be considered in conjunction with the accompanying drawings in which:

FIG. 1 is a perspective showing a typical user wearing the hanger object of the present invention.

FIG. 2 shows a perspective of the hanger object of the present invention, describing basic elements.

FIG. 3a is an isometric view of the hanger assembly showing the front and its external components.

FIG. 3b is an isometric view of the hanger assembly showing the rear face of the hanger and its elements.

FIG. 4a is an isometric view of the hanger body showing the front features.

FIG. 4b is an isometric view of the hanger body showing the internal features.

FIG. 4c is an isometric view of the winding spool showing its features.

FIG. 5a is a projected view of the rear face of the hanger assembly showing the internal components.

FIG. 5b is a projected view of the left side of the hanger assembly with the electronic device attached.

FIG. 6a is a projected view of a simplified hanger body with the purpose of showing a preferred embodiment of the present invention where the gripping elements are keyed to the hanger body for easy exchange.

FIG. 6b is a cross sectional view of the simplified hanger body with the purpose of showing the keyed gripping elements for easy exchange.

FIG. 7a is a cross sectional view along the alternate embodiment of the present invention where gripping element contains features that allow the easy insertion and locking in place of the electronic device.

FIG. 7b is a profile section of the left hand side of the hanger body containing an alternate embodiment for the gripping element which allows easy engagement and disengagement of the electronic device.

FIG. 8 is a partial view of the bare hanger body showing the detachable fixed end of the lanyard as an exemplary method of one of the many ways the fixed end could be easily remove and engage to the hanger body.

### DETAILED DESCRIPTION OF THE INVENTION

Detailed embodiments of the present invention are disclosed herein, however, it is to be understood that the disclosed embodiments are merely exemplary of the invention, which can be embodied in numerous forms. Therefore, specific structural and functional details disclosed herein are not to be interpreted as limiting, but merely as a basis for the claims and as a representative basis for teaching one skilled in the art to variously employ the present invention in virtually any appropriate detailed structure. Further, the terms and phrases used herein are not intended to be limiting; but rather, to provide an understandable description of the invention. While the specification concludes with claims defining the features of the invention that are regarded as novel, it is believed that the invention will be better understood from a consideration of the following description in conjunction with the drawing figures, in which like reference numeral are carried forward.

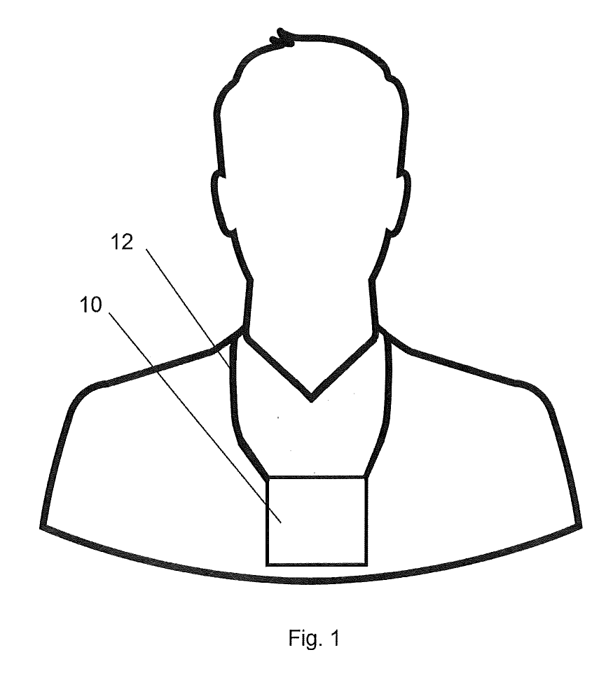

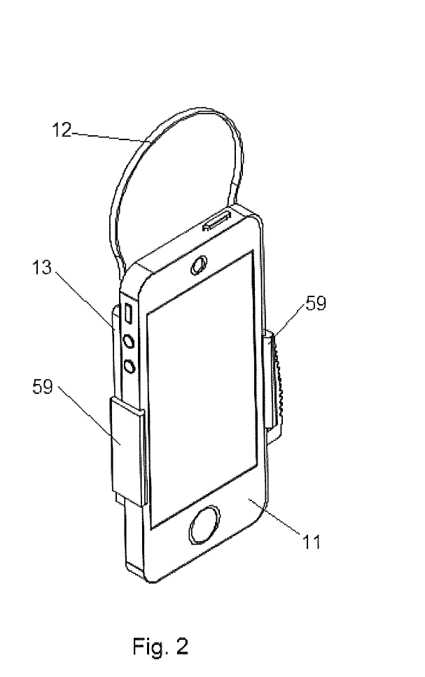

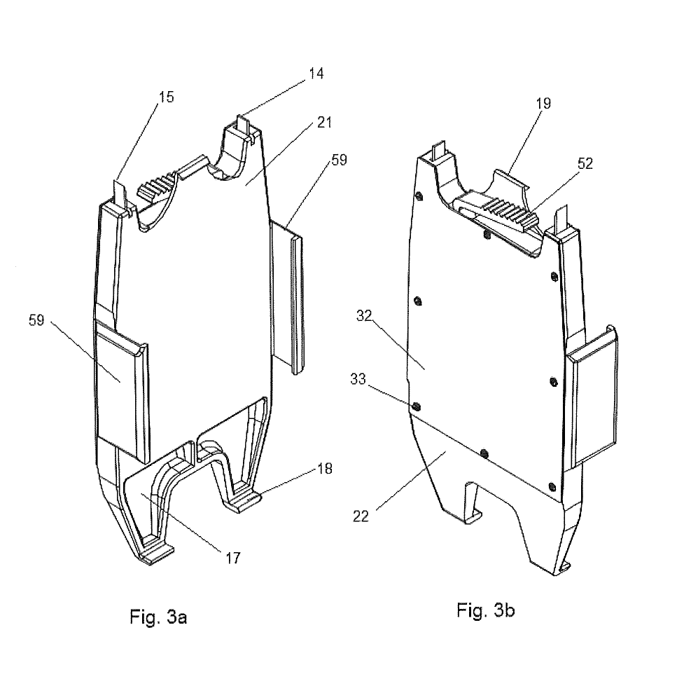

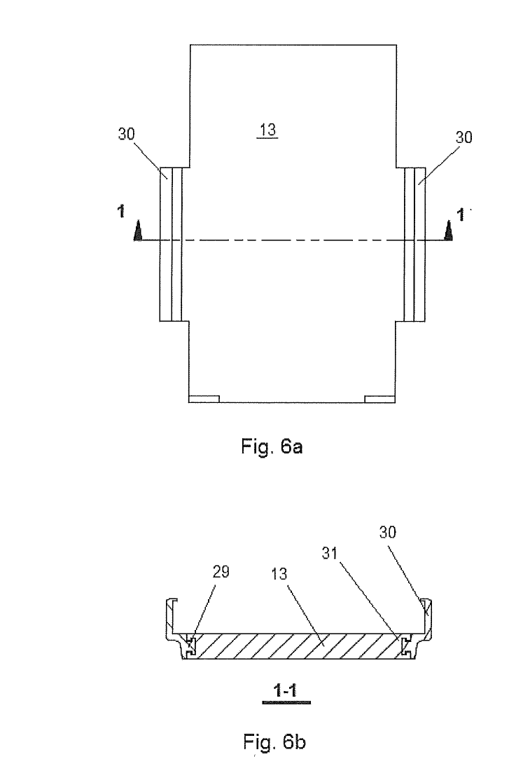

Referring now to FIGS. 1-8, the embodiments of the hanger assembly of the present invention are depicted. As shown by FIG. 1 the hanger assembly 10 is depicted in its intended use mode, hanging from the user's neck by the retractable lanyard 12. FIG. 2 shows one of the embodiments of the hanger assembly 10 exposing the required external elements. Since the preferred manufacturing process for the main components of the housing assembly 10 is plastic molding, parts will be described as plastic molded components which include the necessary features for functionality, it is lightweight, durable and cost effective. The housing 13 is a single plastic molded part that contains the many features required for assembling the necessary components which makes possible the required functionality. The lanyard 12, being a flexible and pliable material, preferably flat shaped, for use around the users neck and to suspend the hanger assembly with the electronic device 11 attached. The grippers 59 for securing the electronic device 11 to the hanger's housing 13. The grippers 59 can adopt many shapes dictated by the electronic device 11 to be attached. The grippers 59 can be molded as an integral part of the hangers housing 13 as shown by FIGS. 3a and 3b, or as separate elements with a custom attachment system as shown by FIGS. 6a and 6b. The housing 13 contains the lanyard retrieval and locking system which allows to fully conceal or extend the lanyard to its maximum length combined with a locking system which allows to maintain certain length of lanyard outside the housing 13, for the purpose of providing an adjustable position for the hanger assembly 10 when in-use. As the housing is manufactured by the process of injection molding, the parts contain cavities called plastic savers 17, to reduce the amount of material and weight as permitted.

The lanyard 12 is preferably a piece of flat and flexible material that is attached to the frame of the housing 13, one end of the lanyard 12 identified as fixed end 14, and the other end is attached into a winding spool 37, denoted as the floating end 15. The flattened shape allows maximize storage capacity within a winding spool 37 and it is more comfortable to the wearer than a cylindrical shaped lanyard since it distributes the device weight over a larger surface area.

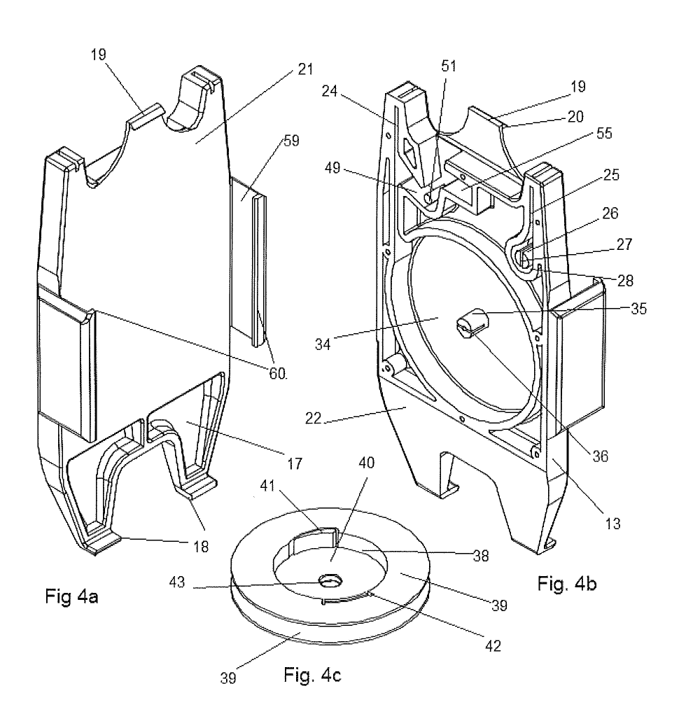

The housing 13, depicted in FIGS. 4a and 4b, contains several structures to locate and allow operation of the several elements of the device. These structures within the housing 13 are the winding spool cavity 34, the lanyard lock lever pocket 49, and the lanyard fixed end pocket 28. The lanyard fixed end pocket 28 containing a lanyard groove 25, a lanyard post 26 and the lanyard post groove 27. These structures within the fixed lanyard pocket 28 for securing the lanyard fixed end 14 to the housing 13. The winding spool cavity 34 is a cylindrical pocket with a central post 35 where a winding spool 37 and winding spring 44 are rotationally disposed. Also contained within the housing 13 is the lanyard lock lever pocket 49, and the lanyard lock lever spring pocket 50. The lanyard lock lever 52 is pivotally disposed within the lock lever pocket 49 around the lock lever post 51. The lock lever 52 is urged by the lock lever spring 57 to pinch the lanyard 12 within the housing lanyard groove 24 within the housing 13, to secure the lanyard within the housing for controlling the external lanyard length. The particular configuration for the lanyard locking system comprises a lock lever 52, which contains a pivot hole 53 to be pivotally disposed over the lock lever post 51 within the lock lever pocket 49. The lock lever 52, also contains a section denoted as lock lever push arm 56 that projects outside the housing 13 to allow the user to actuate such lock lever 52 for releasing the lanyard 12 contained within the housing 13, or for retrieving the lanyard 12 into the housing 13. Depressing the lock lever push arm 56, overrides the force of the lock lever spring 57 which otherwise pushes the lock lever pinch arm 54 against the lanyard 12 and the lanyard groove 24.

The winding spool 37 depicted by FIG. 4, is located within the winding spool cavity of the body 10. The function of the winding spool 37 is to provide storing space for the lanyard 12 within the housing 13 and to provide the force that allows the retrieval of the lanyard 12 inside the housing 13. Within the spool 37 is disposed a winding spring 44. The winding spring 44 for producing torsional motion to the spool 37. The spool 37 is comprised of two axial flanges 39, connected by a center hub 38. The hub 38 contains the winding spring pocket anchor 41, and a center hole 43. The winding spring pocket anchor 41 for anchoring and containment of the winding spring 44, and the center hole 43 for rotationally disposing the spool 37 around a post 35 located within the spool cavity 34. Within the periphery of the spool hub 38 is disposed a winding spring hook groove 41 for anchoring the winding spring outer end 45. Also within the periphery of the spool hub 38 is disposed the lanyard floating end 15 which is secured to the spool 37 by the lanyard anchoring groove 42. The spool spring 44 has an inner end 46 which is fixedly attached to the housing 13 by means of the spool cavity post groove 36. Under this configuration and with the interaction of the corresponding elements, the spool 37 is provided a torsional force by the spring 44, which winds the lanyard 12 within the spool flanges 39. The elements internally contained within the housing 17 are secured in place by a rear face cover 32. The cover 32 is a thin piece of rigid material held in place against the housing 13 by fasteners 33 as shown by FIG. 3b.

Externally disposed in both sides of the housing 13 are a set of grippers 59 to secure a portable electronic device against the housing 13. The housing 13, could be manufactured without such grippers 59, instead a set of interlocking keys 29 and the housing key slot 31 as shown by FIGS. 6a and 6b. These keys 29, could be used to adapt custom grippers 30 for adapting to a variety of electronic device shapes. In addition to the grippers 59, the housing 13 may contain additional structures to restrain movement of the electronic device within the housing 13. The current configuration of the housing 13 which is used for descriptive purposes illustrates a couple of grippers 59, with an undercut 60. The intended purpose of the undercuts 60 is to extend between the gripper 59 walls and towards the face of the electronic device 11. This insures that the electronic device 11 is held between the grippers undercut 60 and the housing front face 21. Since these elements do not fully constrain the electronic device 11 to the housing 13, additional structures are necessary to provide full constrains. These structures as the bottom stoppers 18 and the upper retainer tab 19. As the electronic device is slid against the housing front face 21 and under the grippers undercuts 60, the bottom tabs 18 provide a stopping element in one direction of possible motion. On top of the housing 13 is shown another structure consisting of a flexible tab 19 with a retention hook 20. This flexible tab 19 deflects while the electronic device 11 is inserted into through the housing 13, then the retention hook 20 snaps back onto the upper edge of the electronic device 11 when the bottom edge of such electronic device 11 reaches the bottom tabs 18. The interaction of these holding elements fully constrain the movement of the electronic device 11 within the housing 13. To remove the electronic device from the housing 13, the flexible tab 19 is slightly bend away from the electronic device 11 top edge, while the electronic device 11 is pulled off the housing 13.

As aforementioned, these holding structures grippers 59, bottom tab 18 and flex tab 19 are integral part of the housing and are configured for a predetermined electronic device 13 dimensional envelope. To tame with the problem of different electronic device configurations instead of manufacturing a housing per every different electronic device, a universal housing 13 could be configured in such a way that only few gripping elements are changed to adapt to different geometrical shapes. This is illustrated by FIGS. 6a and 6b where the housing 13 has gripper keys slots 31 and the grippers have matching keys 29.

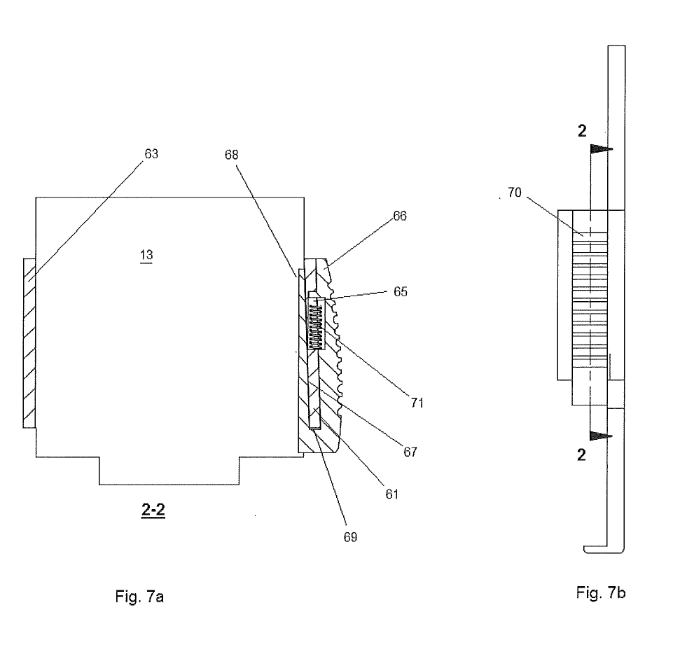

Alternatively to the gripping structures afore described, FIGS. 7a and 7b describes a grippers system that utilizes lateral friction to secure the electronic device 11 within the housing 13, eliminating the need of additional constraining elements on top of the housing 13. This gripper system is shown for illustration purposes as part of the housing, but may also be part of a custom gripper 30 since it is a variation of gripper structure. Under this configuration at least one of the grippers is a single element attached or detachable from the housing. Under this consideration, one gripper wall 63 remains as the straight supporting edge, the other gripper 59 contains a locking element denoted as slide button 66. The slide button 66 inner wall 67 slides against the gripper wall 61, which is slightly inclined. The inclination of the gripper wall 61, moves the slide button friction face 68 laterally against the electronic device 11 side face as the slide button 66 moves upwards against the gripper wall 61. The gripper button 66 is urged against its top position by a slide button spring 71, disposed inside the slide button cavity 69, and the gripper wall pocket 65. The slide button 66 contains a touch face 70 for moving the slide button 66 downwards and release the force acting over the electronic device 11 face.

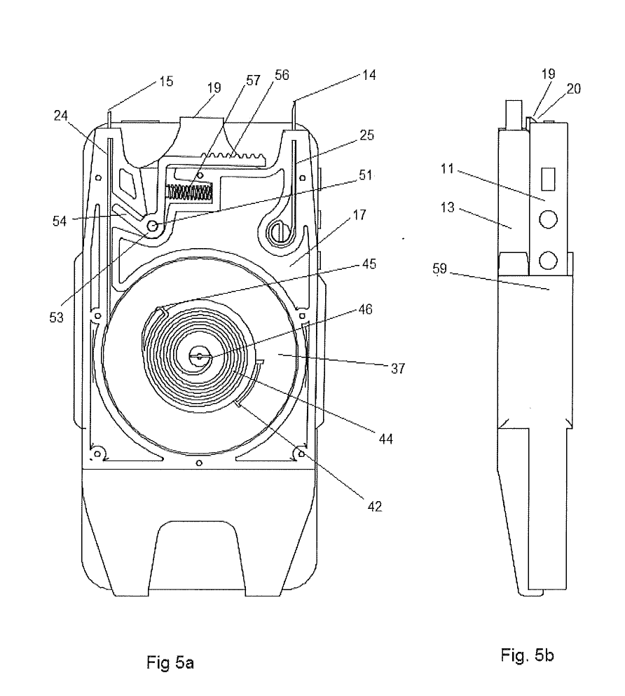

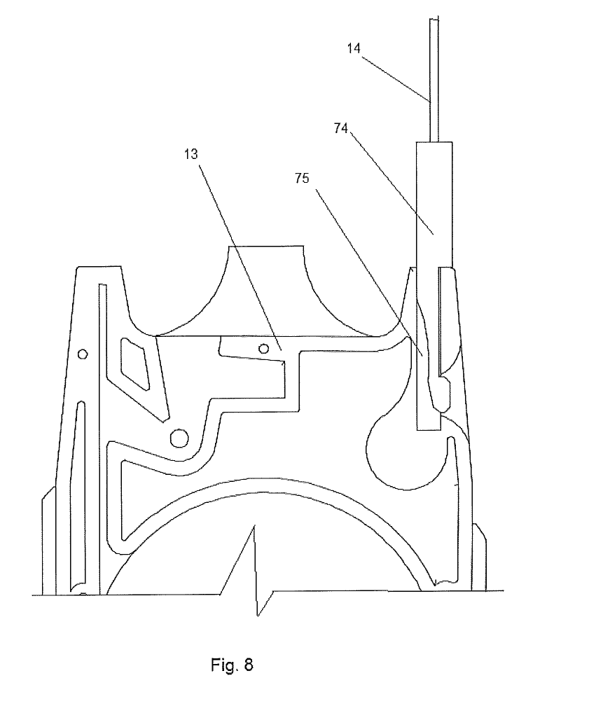

When the hanger assembly 10 coupled with the electronic device 11 is in storage condition, the lanyard is fully wound into the spool 38 as shown by FIGS. 2a, 2b and 5a. When the hanger 10 with the electronic device 11 are ready for use, the user pulls the exposed section of the lanyard 12 as much as he desires, places the lanyard 12 over his/her neck, then adjust the hanger housing 13 height over the chest by using the lock lever push arm 56. In this position, the user can keep close monitoring of the device and can use such electronic device 11 without detaching it from the hanger 10 or his neck. To remove the hanger 10 with the electronic device 11 from his/her neck simply pulls the unit while holding the block lever push arm 56 to easily extend the lanyard 12 length. After the carrier assembly 10 is removed, the user will push the lock lever push arm 56 to fully store the lanyard within the housing 13. The hanger 11 also could be configured in a way that allows easy detachment and attachment of the fixed portion of the lanyard 14 for looping the lanyard around the neck as shown by FIG. 8. In this configuration the lanyard fixed end 14 is attached to an anchoring clip 74 that easily engages or disengages into the housing clip cavity 75.

Many modifications and other embodiments of the invention set forth herein will come to mind to one skilled in the art having the benefit of the teaching presented in the foregoing description and associated drawings. Therefore, it is to be understood that the inventions are not to be limited to the specific embodiments disclosed and that modifications and other embodiments are intended to be included within the scope of the appended claims. Although, specific terms are employed herein, they are used in a generic and descriptive sense only and not for purposes of limitations.

### NUMERICAL REFERENCE

| | |
|---|---|
| 10 | Hanger assembly |
| 11 | Electronic Device |
| 12 | Lanyard |
| 13 | Housing |
| 14 | Lanyard fixed end |
| 15 | Lanyard floating end |
| 16 | |
| 17 | Material saver |
| 18 | Bottom stoppers |
| 19 | Upper tab |
| 20 | Retainer hook |
| 21 | Housing front face |
| 22 | Housing rear face |
| 23 | |
| 24 | Lanyard groove |
| 25 | Fixed end strap groove |
| 26 | Fixed end strap post |
| 27 | Fixed end strap post groove |
| 28 | Lanyard fixed end pocket |
| 29 | Gripper Key |
| 30 | Custom gripper |
| 31 | Housing key slots |
| 32 | Face cover |
| 33 | Face cover fasteners |
| 34 | Spool cavity |
| 35 | Spool cavity post |
| 36 | Spool cavity post slit |
| 37 | Spool |
| 38 | Spool hub |
| 39 | Spool flanges |
| 40 | Spool spring pocket |
| 41 | Spool spring pocket anchor |
| 42 | Spool hub strap anchor |
| 43 | Spool center hole |
| 44 | Spool spring |
| 45 | Spool spring outer end |
| 46 | Spool spring inner end |
| 47 | |
| 48 | |
| 49 | Lock lever pocket |
| 50 | Lock lever spring pocket |
| 51 | Lock lever pocket post |
| 52 | Lock lever |
| 53 | Lock lever pivot |
| 54 | lock lever pinch arm |
| 55 | Lock lever spring pocket |
| 56 | Lock lever push arm |
| 57 | |
| 58 | |
| 59 | Grippers |
| 60 | Gripper undercut |
| 61 | Gripper wall |
| 62 | Gripper wall tab |
| 63 | Gripper wall straight |
| 64 | Gripper wall outer face |
| 65 | Gripper wall pocket |
| 66 | Slide button |
| 67 | Slide button inner wall |
| 68 | Slide button friction face |
| 69 | Slide button cavity |
| 70 | Slide button contact face |
| 71 | Slide button spring |
| 72 | Friction pads |
| 73 | Device side face |
| 74 | Anchoring clip |
| 75 | Housing clip cavity |

What is claimed is:

1. A holder for a wearable portable electronic devices comprising:
a) a housing; and
b) an adjustable lanyard.
said housing including gripping means to securely hold an electronic device, winding means to provide a force for retrieving said retractable lanyard into said housing and locking means to control and maintain said lanyard length outside said housing for adjusting the position of said housing on the user's body.

2. The holder of claim 1, wherein said adjustable lanyard is fully retractable inside said housing for convenient storage when not in use.

3. The holder of claim 1, wherein said housing contain gripping means to easily attached or detach a portable electronic device without blocking controls and viewable screen.

4. The holder of claim 1, wherein said adjustable lanyard has one fixed end permanently attached to said housing and a floating end attached to said winding means.

5. The holder of claim 1, wherein said gripping means are easily interchangeable or adjustable for custom adaptability.

6. The holder of claim 4, wherein said lanyard fixed end is easy detachable and attachable to said housing wherein said adjustable lanyard is detached to loop around the user's neck, and re-attached once said adjustable lanyard is positioned around the user's neck.

7. A necklace comprising:
a) a adjustable lanyard; and
b) a compact electronic device holder.
Said compact electronic device holder including means to fully retract said adjustable lanyard into said compact electronic device holder, and means to selectively control the exposed length of said adjustable lanyard outside said housing. Said adjustable lanyard having a fix end and a floating end. Said compact electronic device holder including gripping means for easily attach or detach a compact electronic device.

8. The necklace of claim 7, wherein said adjustable lanyard is fully retractable inside said compact electronic device holder.

9. The necklace of claim 7, wherein said gripping means are easily interchangeable from said compact electronic device holder.

10. The necklace of claim 7, wherein said gripping means of said compact electronic device holder allow to hold a portable electronic device without blocking controls or viewable screen.

11. An apparatus configured to hang a compact electronic device from a user's neck and to adjust the hanging height comprising:
a) an adjustable lanyard having a first end and a second end; said first end of said adjustable lanyard being fully retractable; and
b) a compact electronic device holder.
Said second end of said lanyard attached to said compact electronic device holder body, said compact electronic device holder having gripping means for selectively attaching or detaching a compact electronic device, winding means to selectively retract said lanyard first end inside said compact electronic device holder body and locking means to selectively maintain the exposed length of said adjustable lanyard for user comfort and convenience.

12. The apparatus of claim 11, wherein said compact electronic device holder has decorative means on one exposed face.

13. The apparatus of claim 11, wherein said lanyard is fully wound inside said compact electronic device holder when said apparatus is not in use or stored.

14. The apparatus of claim 11, wherein said gripping means on said compact electronic device holder allow to hold a portable electronic device without blocking controls or viewable screen.

15. The apparatus of claim 11, wherein said adjustable lanyard fixed end having means for easy detachment or attachment to said compact electronic device holder body wherein said adjustable lanyard is detached to loop around the users neck, and reattached once the adjustable strap is around the users neck.

16. The apparatus of claim 11, wherein said gripping means are easily interchangeable from said compact electronic device holder.
